(19) United States
(12) Patent Application Publication
(10) Pub. No.: US 2003/0188241 A1
(43) Pub. Date: Oct. 2, 2003

(54) CMOS low leakage power-down data retention mechanism

(75) Inventors: Victor V. Zyuban, Peekskill, NY (US); Stephen V. Kosonocky, Wilton, CT (US); David J. Meltzer, Wappingers Falls, NY (US)

Correspondence Address: Eric W. Petraske, 68 Old Hawleyville Road, Bethel, CT, 06801, US

(73) Assignee: International Business Machines Corporation, Armonk, NY

(21) Appl. No.: 10/112,827

(22) Filed: Mar. 29, 2002

(51) Int. Cl. G01R 31/28

(52) U.S. Cl. 714/726

(57) ABSTRACT

A low-power integrated circuit containing a set of scan latches for passing data from flip-flops to test circuitry is modified such that the scan latches are formed from low-leakage transistors connected directly to the power supply so that they remain on during power-down and such that there is a data return path from the scan latches back to the flip-flops, so that the scan latches receive data from the flip-flops before a power-down mode, retain the data during power-down and return the data after power-down, thus saving on circuit area by using the scan latches for a second function. Further area is saved by using the scan trigger input to the flip-flops also for the data return path.

### FIELD OF THE INVENTION

The field of the invention is CMOS integrated circuits containing latches and having the capability of retaining the state of its latches during the power-down mode or sleep modes.

### BACKGROUND OF THE INVENTION

As CMOS process technology is scaling, power supply voltage scales down as well. In order to achieve high speed operation, transistor threshold voltages are scaled down too. Although lowering the threshold voltage reduces circuit delays, it also exponentially increases the subthreshold leakage currants. These leakage currents lead to power dissipation even when the circuit is not doing any useful computations. The resulting standby power presents a serious problem for battery operated devices.

A standard method of reducing the leakage power during inactive intervals is to use multi-threshold CMOS (MTCMOS) technology, together with sleep or power down modes. According to this method, all logic is built of low-threshold transistors, with a high-threshold transistor serving as a footer or a header to cut leakage during the quiescent intervals. During the normal operation mode, the MTCMOS circuits achieve high performance, resulting from the use of low-threshold transistors. During the sleep mode, high threshold footer or header transistors are used to cut off leakage paths, reducing the leakage currents by orders of magnitude. During the power-down mode the state of all circuits connected to the power supply (or ground) through the header or footer is lost. In most cases the state of the circuit needs to be restored on returning from the power-down mode, to resume normal operation. The state of sequential circuits is stored in latches or flip-flops. Consequently, to resume the operation of the sequential circuit after returning from the standby mode, the state of all latches or flip-flops needs to be restored.

### DISCUSSION OF THE PRIOR ART

Several techniques have been developed to save and restore the state of latches during the power-down mode in MTCMOS sequential circuits. These techniques are based on duplicating every regular latch or flip-flop in the circuit with a shadow or balloon latch, and providing a path to move data from the regular flip-flop to the shadow, and back. The balloon, or shadow latch is built of high-threshold devices, and connected to real power and ground (bypassing the footer and header transistors). Since the leakage currents through the high threshold devices are orders of magnitude less than those through the low-threshold transistors, the leakage currents through the balloon latch during the power-down mode are small, and can be neglected.

The prior art balloon latch approach, shown in FIG. 1 and comprising master latch 110, slave latch 120 and balloon latch 130, has a significant area and active power overhead. Adding the balloon latch adds ten extra transistors to the flip-flop, increasing the transistor count from 16 to 26. Inverters 10 and 11 and transmission gate T7, comprising the balloon latch, add 6 transistors to the circuit. Transmission gates T5 and T6 add 4 more transistors to the circuit, that provide the path for moving data between the main latch and the balloon latch. Thus, the area overhead of the balloon latch is estimated as 10/16=63%. Moreover, the balloon latch approach also leads to an increase in delay through the main latch and its active power, because of the extra parasitic capacitance of the two transistors that gate data to and from the balloon latch, transmission gate T6, and the two transistors that have to be added to the feedback path of the slave latch, transmission gate T5.

Another prior art solution to the data retention problem is shown in FIG. 2. The flip-flop comprises a switch T13-T14 which feeds the input into the first (master) latch comprising transistors T15, T16 and T21, T22. A second switch T17-T18 feeds the output of the master latch to the input IN of the second (slave) latch comprising transistors T19, T20 and T23, T24). A third switch T25-T26 connects the output node OUT to the input of the first latch, forming an outside feedback path. The switch T25-T26 is closed during the power-down mode (SLEEP signal is active). Only those transistors that are on the critical path (T13, T14, T15, T16, T17, T18, T19 and T20) need to be fast, and therefore, are implemented as low-threshold devices. All remaining transistors are implemented as high-threshold devices. Sleep mode is entered and exited with PHI_1 inactive and PHI_2 active. PHI_2 also needs to remain active during the entire sleep period. Sleep mode is entered by applying the high level to the SLEEP signal, when PHI_1 is inactive and PHI_2 is active. This closes switch T25-T26, closing the outer feedback loop. The state is preserved by the loop formed by inverters T23-T24, T21-T22, and switches T17-T18 and T25-T26. Since both inverters T23-T24 and T21-T22 that are powered on during the sleep mode are built of high-threshold transistors, the leakage during the power-down mode is significantly reduced.

This outside feedback approach has a significant area overhead, however, because a separate footer and header need to be implemented in every latch, to eliminate all leakage paths. FIG. 2 shows that the footer T28, cutting the leakage through the logic (T11-T12) that feeds data to the latch cannot be used as a footer for the latch, because of the leakage path, shown as a dotted line in FIG. 2. Thus, a separate footer T30 needs to be implemented to cut the leakage through the latch. For the same reason, the header transistor in the latch T29 cannot be merged with the header transistor T27 that cuts leakage through the logic (T11-T12) that feeds data to the latch. Similarly, it can be shown that the footer and the header cannot be shared by different latches.

In order to achieve high speed in the latch, the footer and header transistors in the latch (T30 and T29) have to be sized several times as large as the low threshold devices T15, T16, T19 and T20. This leads to a significant area overhead of the prior art outside feedback approach. Also, the switch T25-T26 on the outside feedback path presents an extra capacitance load at both the input and the output of the latch, resulting in further increase in the active power and a performance penalty.

### SUMMARY OF THE INVENTION

The present invention relates to circuitry for saving and restoring the processor state during power-down mode, with a low overhead in area and power dissipated in the normal operation mode.

A feature of the invention is the dual use of a scan latch for passing data to a test circuit and also for retaining data during power-down mode.

Another feature of the invention is the modification of data flow between a latch and an associated scan latch by adding a path to return data from the scan latch.

### BRIEF DESCRIPTION OF THE DRAWINGS

FIG. 1 illustrates a prior art module for saving data during power-down mode.

FIG. 2 illustrates another prior art module for saving data during power-down mode.

FIG. 3 illustrates a block diagram of a prior art scan latch.

FIGS. 4A-4C illustrate implementations of the example of FIG. 3.

FIG. 5 illustrates a block diagram of an embodiment of the invention.

FIGS. 6A and 6B illustrate an implementation of the embodiment of FIG. 5.

FIG. 7 illustrates an alternative embodiment of the invention.

### DETAILED DESCRIPTION OF THE PREFERRED EMBODIMENT

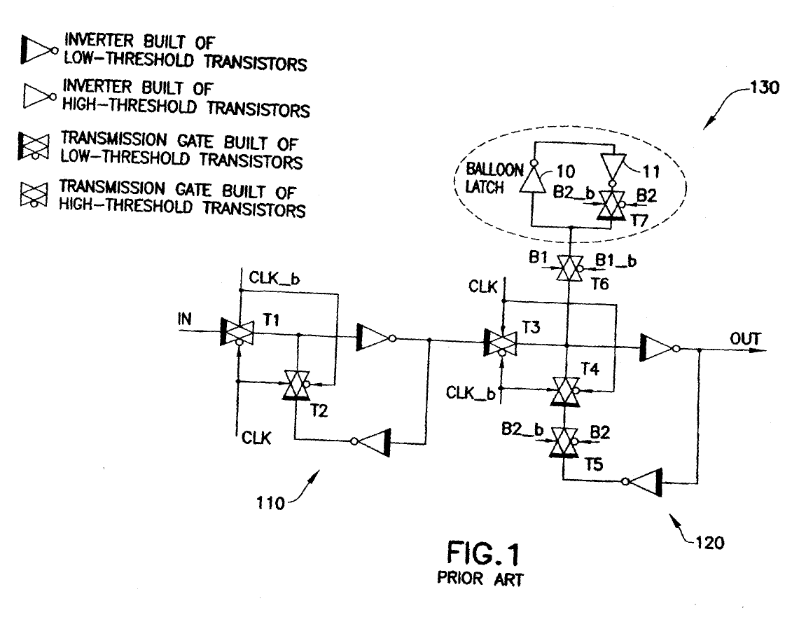

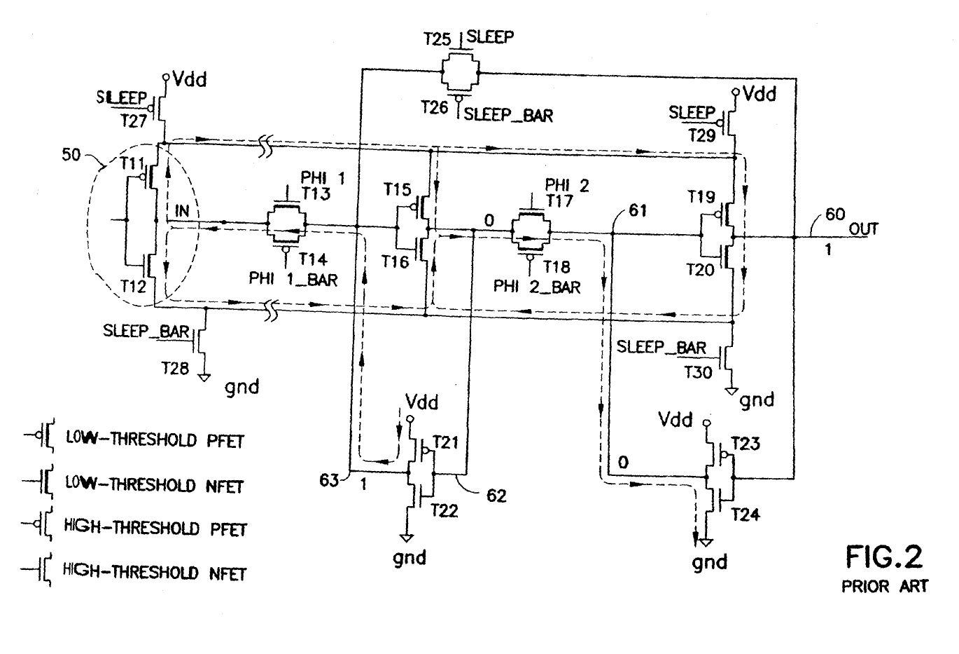

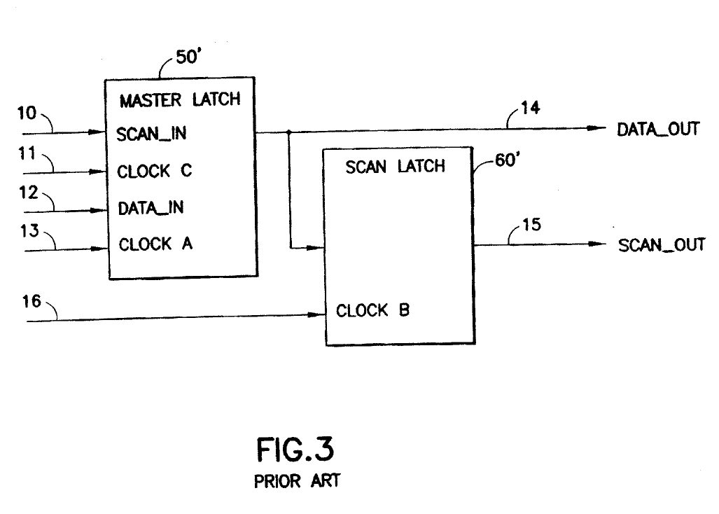

FIG. 3 shows a block level view of a typical prior art level-sensitive scan mechanism for a single-phase latch (not having power-down capability). Scanning is used in a test mode to pass the data in the circuit to test circuitry. Accordingly, latch 60′ taps on to the master latch output on line 14 and passes a scan output on a separate line to the test circuitry. The master latch 50′ is a fast single-phase latch, controlled by clock C, 11. It has data input 12 and data output 14, as well as scan input 10 and scan clock A, 13. The master latch 50′ can be any type of a single phase latch, for example, an edge triggered latch, or pulsed latch. The scan latch 60′ is a (possibly) slow level-sensitive latch, controlled by clock B, 16. The output of the scan latch 15 is the scan output of the entire flip-flop. It is connected to the scan input 10 of another latch in the scan chain. The scan latch can be implemented as any type of level-sensitive latch. During normal operation mode, clock A, 13 and clock B, 16 are kept at the low level, and the flip-flop works as a conventional single-phase latch, controlled by clock C, 11. The scan latch is in the non-transparent state, so that the scan output does not toggle, and the internal capacitances inside the scan latch do not toggle either. This reduces the power dissipation in the normal operation mode. During the scan mode, clock C, 11 is kept at the low level, and the flip-flop works as a master-slave latch, controlled by non-overlapping clocks A, 13 and B, 16. This provides a robust, level-sensitive scan operation. There is no provision in the circuit of this Figure for data retention during power-down mode. The prior art would have implemented a balloon latch as in FIG. 1, or equivalent.

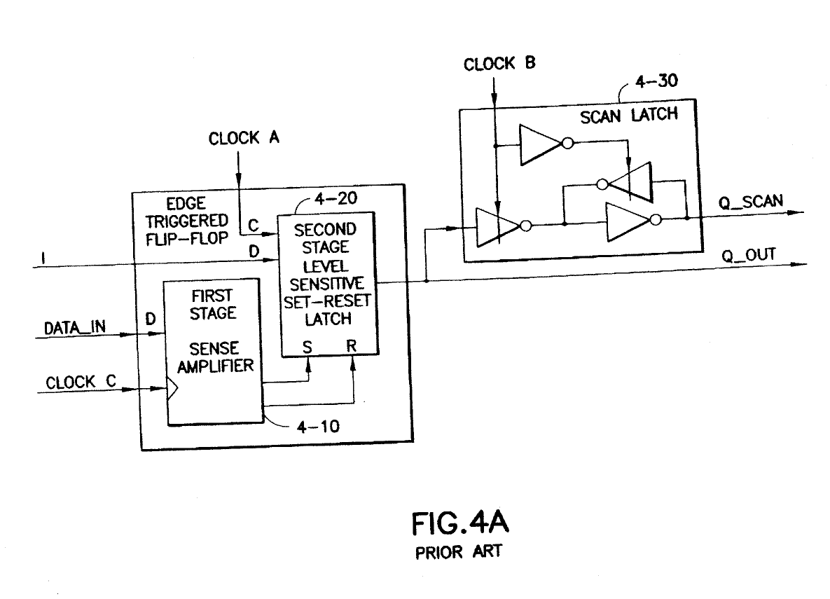

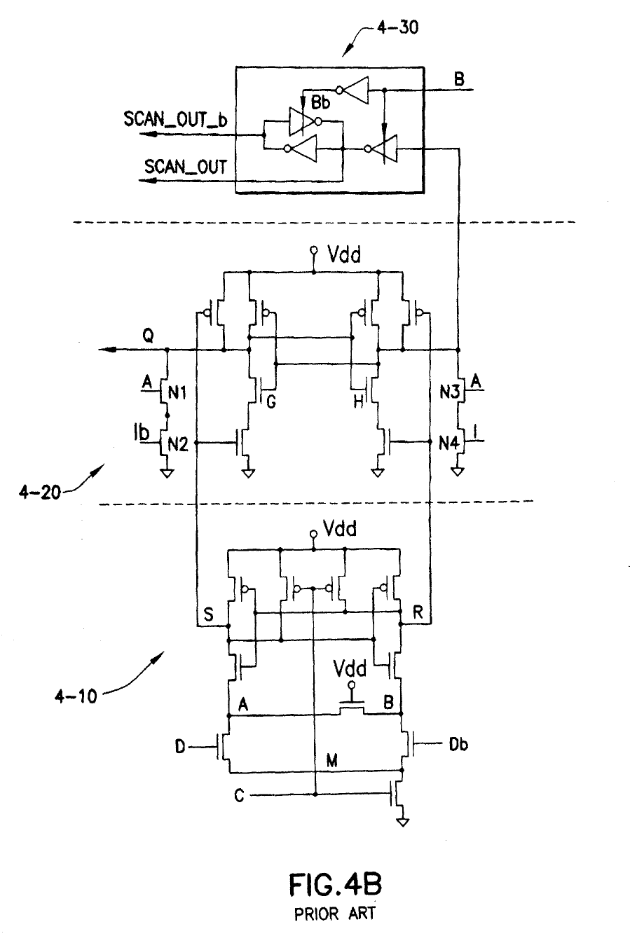

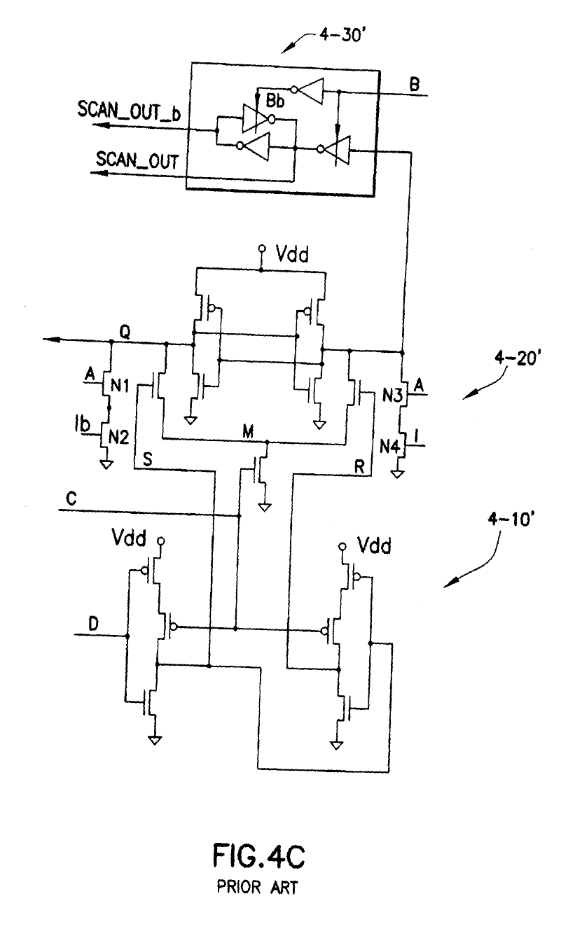

FIG. 4 shows implementation examples of the prior art scan mechanism shown in FIG. 3. FIG. 4A shows the next level of detail, in a particular embodiment of latch 50 and scan latch 60. FIG. 4B shows one embodiment of the block diagram in FIG. 4A. In FIG. 4B, the sense amp latch 4-10 is shown at the bottom, the second stage level sensitive set-reset latch 4-20 is shown in the middle and the scan latch 4-30 is shown at the top. Many other forms of latches can be used to carry out these functions and FIG. 4C illustrates another version 4-10′, 4-20′ and 4-30′.

In FIG. 4B, the scanning function is achieved by mixing in the scan-in data at the second stage of the latch. The scan-in data signal, I is written to the second stage of the latch through transistors N1 and N2, or N3 and N4. A high level on clock A enables the scan-in write operation to write data into the second level 4-20 of the latch.

The scan latch 4-30 in FIGS. 4A-4C is a level sensitive latch controlled by clock B. The arrows entering the side of inverters denote enabling the tri-state inverters. When the signal is high, the inverter is enabled and when it is low, the output of the inverter is “tri-stated” for a high impedance connection to the output line. During the scan mode, clock C is kept at the low level, and the second stage 4-20 of the latch and the scan latch work as a master-slave latch, controlled by clocks A and B, providing a level-sensitive scan operation. During the normal operation mode, clocks A and B are kept at the low level, and the latch operates as a conventional latch. The power overhead of this scan provision is only the drain capacitance of two minimum-sized transistors N1 and N3, connected to the output nodes. This extra capacitance is charged or discharged at most once per clock cycle, and is not affected by spurious transitions at the data input.

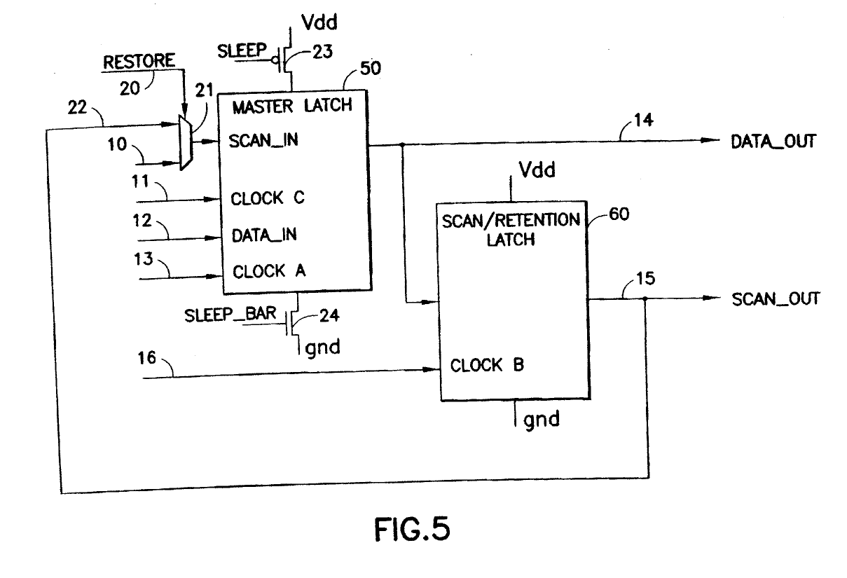

FIG. 5 shows an embodiment of the present invention, based on the module of FIG. 4. In a latch according to the invention, scannable latch 60 has data retention capability during sleep mode as well as storing scan data. The new flip-flop with retention according to the invention uses scan latch 60 both for its original function and also as a high threshold storage module for retaining data during the sleep mode. In order to accomplish this result, retention scan latch 60 is modified as explained below and an extra data path 22 (passing through added multiplexer 21) is provided for restoring the data from retention latch 60 to the main flip-flop 50.

The retention latch 60 is now built of low-leakage devices, such as high threshold transistors, or regular transistors with back bias capability (the well containing the transistors can be back biased), or other low-leakage transistor structures (collectively referred to for purposes of the claims as “retention transistors”). The structure of a retention device will depend on the type of leakage that is of concern—gate leakage is best addressed by the use of thick gate oxide, while subthreshold leakage may be addressed by a different threshold implant to raise the transistor threshold. Real ground and real Vdd (referred to as a reference voltage) are used as power terminals in the retention latch 60. Latch 50 will be built of low threshold transistors, and it may use either virtual Vdd with a header 23, and/or virtual ground with a footer 24, to cut the leakage path during the power-down mode.

During normal operation mode, clocks A and B are kept at the low level, and the latch operates as a conventional latch. During the scan mode, the RESTORE signal 20 is kept at the low level, disabling MUX 21, and the latch works as a master-slave latch, controlled by clocks A and B, as described earlier with respect to FIG. 4. The state of the RESTORE signal during normal operation does not matter.

When entering the power-down mode, a high level on clock B saves data in the retention latch, using output line 14 as the source. On returning from the power-down mode, a high level is applied to the RESTORE signal, and a high level on clock A restores data from the retention latch 60 to the main flip-flop 50, passing out terminal 15 and through MUX 21.

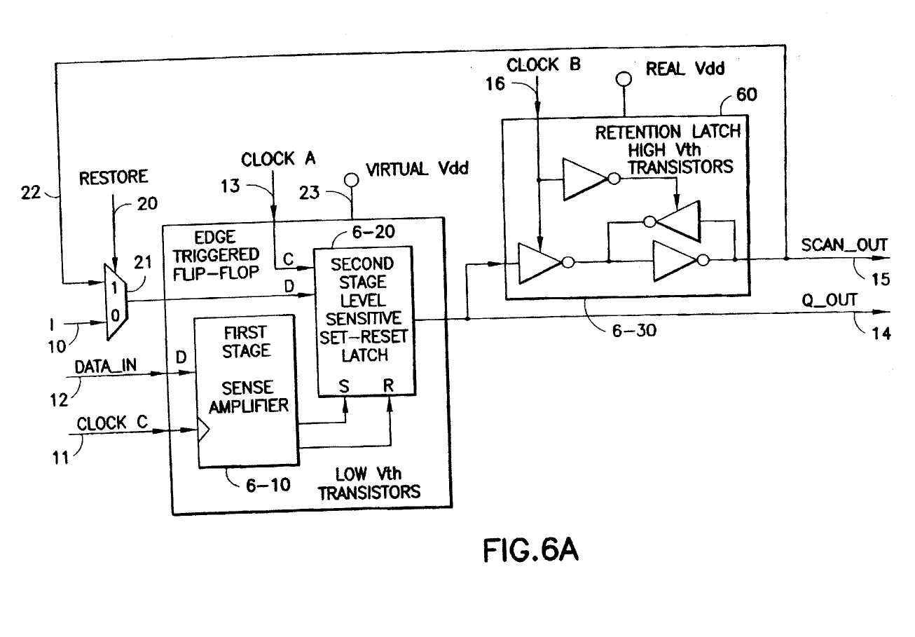

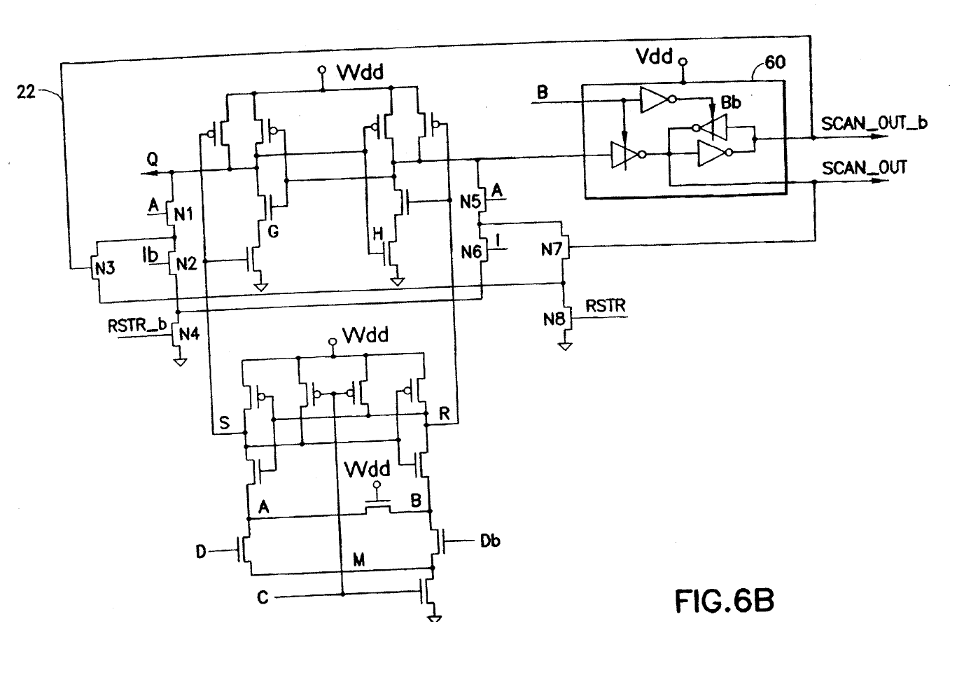

FIGS. 6A and 6B show an example of implementing the inventive data retention mechanism in an edge-triggered sense amplifier latch. The scan/retention latch 60 has the same circuit configuration as that in FIG. 4, but is built of retention transistors. The retention latch uses the real power and ground terminals (referred to as “direct terminals”). The main latch is built of fast, and possibly leaky, transistors. Virtual Vdd with a header is used as a power terminal, to cut the leakage during the sleep or power-down mode. Any combination of header and footer implementations can be used. The path for restoring data from the retention latch to the main latch is implemented as line 22 passing through multiplexer 21. The combination of line 22 and the transistors that pass the state of latch 60 to latch 50 will be referred to as “data restore means”. Multiplexer 21 in FIG. 5 is shown in FIG. 6B as transistors N2, N3, N4, N6, N7 and N8.

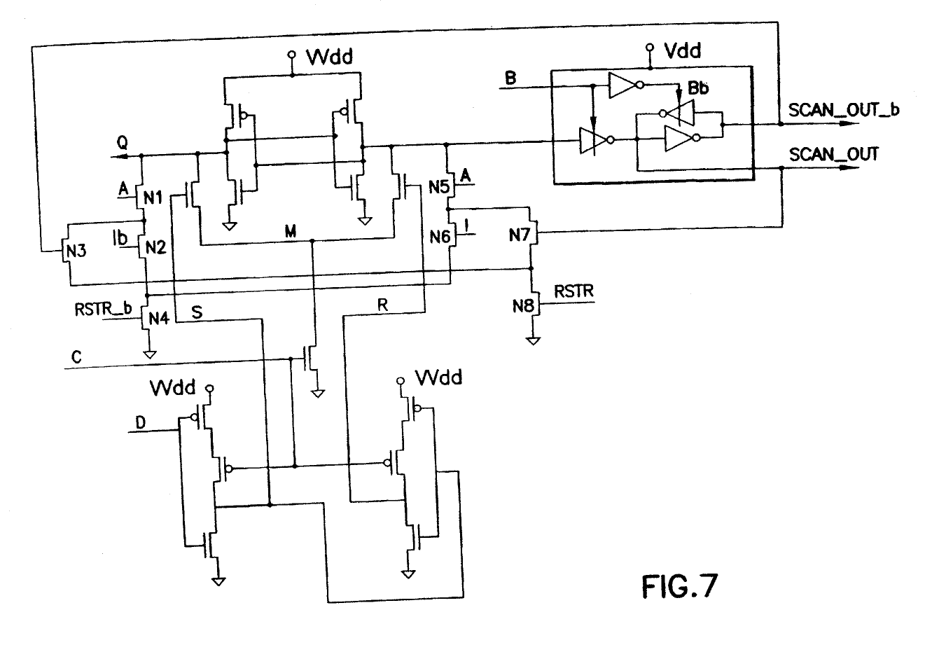

Although FIG. 6 shows the inventive data retention mechanism used with a specific sense amplifier latch, it can also be applied to a variety of scannable latches, including edge-triggered and pulsed latches. FIG. 7 gives an example of applying the inventive data retention mechanism to a semi-static true single phase SRAM latch.

The power and delay overhead of the retention mechanism, disclosed in this patent is reduced to a minor increase in capacitances of internal wires, due to some increase in the area of the flip flop (four extra NFETs in the implementation in FIGS. 6 and 7, N3, N4, N7 and N8). No extra capacitance of transistor gates, sources or drains is added to any nodes that are switching during the normal operation mode. This feature makes the inventive retention mechanism particularly attractive for low-power applications, where minimizing both active and standby power is important

The inventive data retention mechanism can be used, without any modifications, as a checkpointing mechanism to checkpoint (or save) the pipeline state of a processor on any exception event, such as an interrupt, and restore the state on returning to the normal execution flow. In that case, logic on (or off) the chip senses the exception event and activates clock B to save the state and activates clock A to restore data as desired by the system designer. Those skilled in the art are readily able to manipulate the logic signals in the embodiments shown here, using a logic complement instead of the original signal shown here, as is convenient.

The foregoing has described a method to extend the functions of a set of scan latches that are connected to a set of circuit modules containing low-threshold transistors in a circuit configuration, so that the set of scan latches comprise retention transistors and not only controllably pass (in response to a scan control signal) state data from the subset of circuit modules connected to them to test circuitry, which is their original purpose, but also controllably restore state data to the corresponding circuit modules that they are connected to through the path of the data retention means; e.g. in response to the end of a power-down mode.

Initiating a power-down mode can be described generally as an exception event (e.g. the passage of time since the last keystroke being the triggering event). Those skilled in the art are aware that there are other exception events that give rise to the need to store state data. The method described here can also be applied to such exception events by connecting the logic that response to the exception event to the logic that initiates a power-down mode, so that the exception event triggers the process of retaining data also. For example, the triggering signals for power down and for as many exception events as desired could be fed into a multiplexer that triggers the data retention process in response to any of them.

While the invention has been described in terms of a preferred embodiment and some alternatives, those skilled in the art will recognize that the invention can be practiced in various versions within the spirit and scope of the following claims.

We claim:

1. An integrated circuit comprising at least one scannable latch having a main latch and a scan latch coupled thereto, for passing data out of said main latch in response to a scan control signal; in which:
said scan latch comprises at least one retention transistor, whereby data may be retained in said scan latch during power-down mode and said scan latch performs data transfer during scan mode and also data retention during said power-down mode.

2. An integrated circuit according to claim 1; in which:
said scan latch is comprised of retention transistors;
said master latch is isolated from at least one of a reference voltage and ground during said power-down mode by a controllable retention transistor; and
said scan latch has direct connections to at least one of ground and a reference voltage.

3. An integrated circuit according to claim 1; in which:
said scan latch is controllably coupled to said master latch;
said scan latch is formed from retention transistors to hold data in a low leakage mode; and
said master latch is coupled through data retention means to receive retained data upon return from said power-down mode.

4. An integrated circuit according to claim 2; in which:
said scan latch is controllably coupled to said master latch;
said scan latch is formed from retention transistors to hold data in a low leakage mode; and
said master latch is coupled through data retention means to receive retained data upon return from said power-down mode.

5. An integrated circuit according to claim 3, further comprising:
logic for sensing an exception event and retaining data from said master latch in said scan latch; and
logic for restoring said data to said master latch.

6. An integrated circuit according to claim 4, further comprising:
logic for sensing an exception event and retaining data from said master latch in said scan latch; and
logic for restoring said data to said master latch.

7. A method for forming an integrated circuit comprising the steps of:
forming a set of circuit modules containing low-threshold transistors and connecting said set of circuit modules in a circuit configuration;
forming a set of scan latches comprising retention transistors and connected to a subset of said set of circuit modules, for controllably passing state data from said subset of said set of circuit modules to test circuitry in response to a scan signal;
forming a set of data retention means connected between at least one of said set of scan latches and a corresponding circuit module, for controllably restoring said state data to said corresponding circuit module; and
forming control logic connected to said at least one of said set of scan latches and said corresponding circuit module, for controlling said subset of said set of circuit modules to pass state data representing the state of said subset of said set of circuit modules to said set of scan latches in response to a first triggering state of said integrated circuit and to pass said state data representing the state of said subset of said set of circuit modules from said set of scan latches back to said subset of said set of circuit modules.

8. A method according to claim 7, in which said first triggering state initiates a power-down mode of said integrated circuit, whereby said set of scan latches operate to process scan data and also to retain state data during power-down mode.

9. A method according to claim 7, in which said first triggering state responds to an exception event in said integrated circuit, whereby said set of scan latches operate to process scan data and also to retain state data in response to said exception event.

10. A method according to claim 8, in which said first triggering state responds to an exception event in said integrated circuit, whereby said set of scan latches operate to process scan data, to retain state data during power-down mode and also to retain state data in response to said exception event.
